(19) United States
(12) Patent Application Publication
(10) Pub. No.: US 2015/0108435 A1
(43) Pub. Date: Apr. 23, 2015

(54) ORGANIC LIGHT-EMITTING DEVICE

(71) Applicant: Samsung Display Co., Ltd., Yongin-City (KR)

(72) Inventors: Myung-Soo Huh, Yongin-City (KR); Sung-Chul Kim, Yongin-City (KR); Jae-Hyun Kim, Yongin-City (KR); Jin-Kwang Kim, Yongin-City (KR)

(73) Assignee: Samsung Display Co., Ltd., Yongin-City (KR)

(21) Appl. No.: 14/264,234

(22) Filed: Apr. 29, 2014

(30) Foreign Application Priority Data
Oct. 18, 2013 (KR) 10-2013-0124922

(51) Int. Cl. H01L 51/52

(52) U.S. Cl. CPC H01L 51/5253
USPC 257/40

(57) ABSTRACT

An organic light-emitting device includes a substrate, an organic light-emitting diode on the substrate and including a first electrode, a second electrode, and an intermediate layer between the first electrode and the second electrode, and an encapsulation layer covering the organic light-emitting diode. The encapsulation layer includes a first inorganic layer, a first stress control layer and a first organic layer which are sequentially stacked. A Young's modulus of the first stress control layer is greater than a Young's modulus of the first inorganic layer.

This application claims priority to Korean Patent Application No. 10-2013-0124922, filed on Oct. 18, 2013, and all the benefits accruing therefrom under 35 U.S.C. §119, the disclosure of which is incorporated herein in its entirety by reference.

### BACKGROUND

1. Field

One or more exemplary embodiment of the invention relates to an organic light-emitting device.

2. Description of the Related Art

Exemplary embodiments of the invention relate to an organic light-emitting device and a method of manufacturing the same, and more particularly, to an organic light-emitting device which includes an organic layer, an inorganic layer, and an encapsulation layer that includes an intermixing region of an organic material constituting the organic layer and an inorganic material constituting the inorganic layer, and a method of manufacturing the same. Since the encapsulation layer of the organic light-emitting device may have excellent oxygen and moisture barrier performance and may be formed as an ultra-thin film, the organic light-emitting device may have long lifetime and high brightness. Also, since the method of manufacturing the organic light-emitting device is a simple process, manufacturing costs may be reduced.

An organic light-emitting diode is a self light-emitting display that electrically excites a fluorescent organic compound to emit light. Since the organic light-emitting diode may be operated at a relatively low voltage, may be easily formed in a relatively thin profile, and may have wide viewing angles and fast response speeds, the organic light-emitting diode has received attention for use in an advanced display that may address limitations of a light source in a liquid crystal display.

The organic light-emitting diode includes an intermediate layer including of an organic material, between an anode and a cathode. In an organic electroluminescent device, holes injected from the anode move to the intermediate layer via a hole transport layer as cathode and anode voltages are respectively applied to the cathode and the anode, and electrons move from the cathode to the intermediate layer via an electron transport layer so that excitons may be generated by the recombination of the electrons and the holes in the intermediate layer.

Since fluorescent molecules of the intermediate layer emit light as the excitons change from an excited state to a ground state, an image may be formed in the display. With respect to a full-color type organic electroluminescent device, pixels that emit red R, green G, and blue B color are included therein to realize a full color.

As described above, the organic light-emitting diode includes the cathode in contact with the organic layer. The organic light-emitting diode must be protected from the penetration of moisture and oxygen in order to improve the reliability of the organic light-emitting diode.

### SUMMARY

One or more exemplary embodiment of the invention includes an organic light-emitting device.

According to one or more exemplary embodiment of the invention, an organic light-emitting device includes: a substrate; an organic light-emitting diode on the substrate and including a first electrode, a second electrode, and an intermediate layer between the first electrode and the second electrode; and an encapsulation layer covering the organic light-emitting diode. The encapsulation layer includes a first inorganic layer, a first stress control layer and a first organic layer which are sequentially stacked. A Young's modulus of the first stress control layer is greater than a Young's modulus of the first inorganic layer.

A Young's modulus of the first stress control layer may be in a range of about 110 gigapascals (GPa) to about 1,000 GPa.

A Young's modulus of the first inorganic layer may be in a range of about 40 GPa to about 90 GPa.

The first stress control layer may include AlOₓ, poly-diamond, TiC, SiC, WC, tungsten (W), or molybdenum (Mo).

A thickness of the first stress control layer may be in a range of about 0.5 nanometer (nm) to about 15 nm.

The thickness of the first stress control layer may be about 2.5 nm or less.

A critical adhesion between the first stress control layer and the first organic layer may be in a range of about 0.01 newton per meter (N/m) to about 0.3 N/m.

The encapsulation layer may further include a second stress control layer and a second inorganic layer sequentially stacked on the first organic layer, and a Young's modulus of the second stress control layer may be greater than a Young's modulus of the second inorganic layer.

The encapsulation layer may further include a third stress control layer and a second organic layer sequentially stacked on the second inorganic layer, and a Young's modulus of the third stress control layer may be greater than the Young's modulus of the second inorganic layer.

The organic light-emitting device may further include a protective layer between the organic light-emitting diode and the encapsulation layer.

According to one or more exemplary embodiment of the invention, an organic light-emitting device includes: a substrate; an organic light-emitting diode on the substrate and including a first electrode, a second electrode, and an intermediate layer between the first electrode and the second electrode; and an encapsulation layer covering the organic light-emitting diode. The encapsulation layer includes a first organic layer, a first stress control layer and a first inorganic layer which are sequentially stacked. A Young's modulus of the first stress control layer is greater than a Young's modulus of the first inorganic layer.

A Young's modulus of the first stress control layer may be in a range of about 110 GPa to about 1,000 GPa.

A Young's modulus of the first inorganic layer may be in a range of about 40 GPa to about 90 GPa.

The first stress control layer may include AlOₓ, poly-diamond, TiC, SiC, WC, tungsten (W), or molybdenum (Mo).

A thickness of the first stress control layer may be in a range of about 0.5 nm to about 15 nm.

The thickness of the first stress control layer may be about 2.5 nm or less.

A critical adhesion between the first stress control layer and the first organic layer may be in a range of about 0.01 N/m to about 0.3 N/m.

The encapsulation layer may further include a second stress control layer and a second organic layer sequentially stacked on the first inorganic layer. A Young's modulus of the second stress control layer may be greater than the Young's modulus of the first inorganic layer.

The encapsulation layer may further include a third stress control layer and a second inorganic layer sequentially stacked on the second organic. A Young's modulus of the third stress control layer is greater than a Young's modulus of the second inorganic layer.

The organic light-emitting device may further include a protective layer between the organic light-emitting diode and the encapsulation layer.

### BRIEF DESCRIPTION OF THE DRAWINGS

These and/or other features will become apparent and more readily appreciated from the following description of the embodiments, taken in conjunction with the accompanying drawings in which:

FIG. 1 is a cross-sectional view illustrating an exemplary embodiment of an organic light-emitting device, according to the invention;

FIG. 2 is a cross-sectional view illustrating another exemplary embodiment of an organic light-emitting device, according to the invention;

FIG. 3 is a cross-sectional view illustrating still another exemplary embodiment of an organic light-emitting device, according to the invention; and

FIG. 4 is a cross-sectional view illustrating yet another exemplary embodiment of an organic light-emitting device, according to the invention.

### DETAILED DESCRIPTION

Reference will now be made in detail to embodiments, examples of which are illustrated in the accompanying drawings, where like reference numerals refer to like elements throughout. In this regard, the exemplary embodiments may have different forms and should not be construed as being limited to the descriptions set forth herein. Accordingly, the exemplary embodiments are merely described below, by referring to the figures, to explain features of the invention.

While the invention is amenable to various modifications and alternative forms, specific exemplary embodiments have been shown by way of example in the drawings and are described in detail below. Effects and features of the invention, and implementation methods thereof will be clarified through following exemplary embodiments described with reference to the accompanying drawings. The invention may, however, be embodied in different forms and should not be construed as limited to the exemplary embodiments set forth herein.

Hereinafter, exemplary embodiments of the invention will be described in detail with reference to the accompanying drawings. Like reference numerals in the drawings denote like elements, and thus their description will be omitted.

It will be understood that although the terms “first,” “second,” etc. may be used herein to describe various components, these components should not be limited by these terms. These components are only used to distinguish one component from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “on,” another layer, region, or component, it can be directly or indirectly on the other layer, region, or component. That is, for example, intervening layers, regions, or components may be present. As used herein, the term “and/or” includes any and all combinations of one or more of the associated listed items.

Sizes of elements in the drawings may be exaggerated for convenience of explanation. In other words, since sizes and thicknesses of components in the drawings are arbitrarily illustrated for convenience of explanation, the following exemplary embodiments are not limited thereto. Expressions such as “at least one of,” when preceding a list of elements, modify the entire list of elements and do not modify the individual elements of the list.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the invention will be described in more detail with reference to the accompanying drawings.

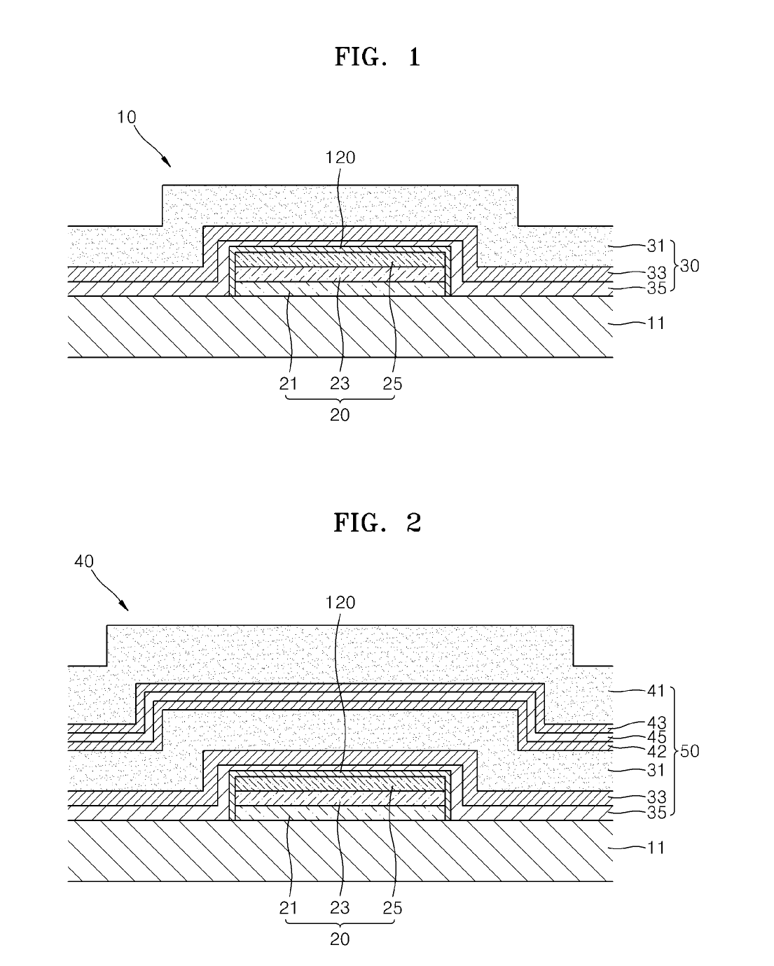

FIG. 1 is a cross-sectional view illustrating an exemplary embodiment of an organic light-emitting device 10, according to the invention. The organic light-emitting device 10 illustrated in FIG. 1 includes an organic light-emitting diode 20, which includes a first electrode 21, an intermediate layer 23, and a second electrode 25, on a substrate 11, and also includes an encapsulation layer 30 covering the organic light-emitting diode 20. The encapsulation layer 30 has a structure, in which a first inorganic layer 35, a first stress control layer 33, and a first organic layer 31 are sequentially stacked, and a Young's modulus of the first stress control layer 33 is greater than a Young's modulus of the first inorganic layer 35.

The substrate 11 may have excellent mechanical strength, thermal stability, transparency, surface smoothness, ease of handling and waterproofness. The substrate 11 may include a glass substrate or a plastic substrate. Although not illustrated in FIG. 1, various modifications may be possible, for example, a planarization layer and/or an insulating layer may be further included on the substrate 11.

The organic light-emitting diode 20 is disposed on the substrate 11. The organic light-emitting diode 20 may include the first electrode 21, the intermediate layer 23 and the second electrode 25.

In an exemplary embodiment of manufacturing the organic light-emitting device 10, the first electrode 21 may be formed by vacuum deposition or sputtering, and may be a cathode or an anode of the organic light-emitting diode 20. The first electrode 21 may have a single layer structure. The first electrode 21 may be a transparent electrode, a semi-transparent electrode or a reflective electrode, and may include indium tin oxide (“ITO”), indium zinc oxide (“IZO”), tin oxide (SnO₂), zinc oxide (“ZnO”), aluminum (Al), silver (Ag), or magnesium (Mg). However, the first electrode 21 is not limited thereto. Also, various modifications may be possible, for example, the first electrode 21 may have a structure of two or more layers using two or more different materials.

In an exemplary embodiment of manufacturing the organic light-emitting device 10, the second electrode 25 may be formed by vacuum deposition or sputtering, and may be a cathode or an anode of the organic light-emitting diode 20. The second electrode 25 may have a single layer structure. A metal with a low work function, an alloy, an electrically conductive compound, and a mixture thereof may be used as a metal for forming the second electrode 25. Specific examples of the metal for forming the second electrode 25 include, but are not limited to, lithium (Li), Mg, Al, Al—Li, calcium (Ca), Mg-indium (In), and Mg—Ag. Also, various modifications may be possible, for example, the second electrode 25 may have a structure of two or more layers using two or more different materials.

The intermediate layer 23 is between the first electrode 21 and the second electrode 25. The intermediate layer 23 may include an organic emission layer. As another exemplary embodiment, the intermediate layer 23 may include an organic emission layer and in addition, may further include at least one of a hole injection layer (“HIL”), a hole transport layer (“HTL”), an electron transport layer (“ETL”), and an electron injection layer (“EIL”). The invention is not limited thereto. The intermediate layer 23 may include an organic emission layer and may further include other various functional layers.

A protective layer 120 may be further included on the organic light-emitting diode 20. The protective layer 120 may have a single layer structure. The protective layer 120 may include an organic material or an inorganic material which may prevent the oxidation of the second electrode 25 of the organic light-emitting diode 20 due to moisture and oxygen. Also, various modifications may be possible, for example, the protective layer 120 may include an organic/inorganic composite layer.

In FIG. 1, the encapsulation layer 30 may cover the organic light-emitting diode 20. The encapsulation layer 30 may include the first inorganic layer 35 and the first organic layer 31. The first stress control layer 33 having a higher Young's modulus than that the first inorganic layer 35 may be included between the first inorganic layer 35 and the first organic layer 31.

The inorganic layer 35 may include one or more materials selected from SiN_{X}, ZrOₓ, poly-silicon (Si), a-Si, Al, copper (Cu), chromium (Cr), gold (Au), Ag, tantalum (Ta) and alloys, Mg and alloys, steels, nickel (Ni)-based alloys, cobalt (Co)-based alloys, zirconium (Zr) and alloys, polycarbonate and diamond-like carbon (“DLC”). The Young's modulus of the first inorganic layer 35 may be in a range of about 40 gigapascals (GPa) to about 90 GPa. The first inorganic layer 35 may be a nitride-based layer. A cross-sectional thickness of the first inorganic layer 35 may be in a range of about 30 nanometers (nm) to about 4,000 nm. In an exemplary embodiment of manufacturing the organic light-emitting device 10, the first inorganic layer 35 may be formed by magnetron sputtering (reactive), plasma enhanced chemical vapour deposition (“PECVD”), E-beam evaporation, arc evaporation (“ARE”), thermal evaporation and/or ion beam deposition (with sputter).

The first organic layer 31 may include one or more materials selected from an acryl-based resin, a methacryl-based resin, polyisoprene, a vinyl-based resin, an epoxy-based resin, a urethane-based resin, a cellulose-based resin and a perylene-based resin.

The first stress control layer 33 may be disposed between the first inorganic layer 35 and the first organic layer 31. The Young's modulus of the first stress control layer 33 may be greater than the Young's modulus of the first inorganic layer 35. The first stress control layer 33 may include AlOₓ, poly-diamond, TiC, SiC, WC, tungsten (W), or molybdenum (Mo). The Young's modulus of the first stress control layer 33 may be in a range of about 110 GPa to about 1,000 GPa. The first stress control layer 33 may be an oxide-based layer. A cross-sectional thickness of the first stress control layer 33 may be in a range of about 0.5 nm to about 15 nm. In an exemplary embodiment of manufacturing the organic light-emitting device 10, the first stress control layer 33 may be formed by atomic layer deposition (“ALD”), pulsed laser deposition (“PLD”), diode sputtering (non-magnetron sputtering), facing target sputtering (“FTS”) and/or PECVD.

In a manufacturing process of the organic light-emitting device 10, a process temperature may be changed between about 25 degrees Celsius (° C.) to about 450° C. Where the encapsulation layer 30 has a stacked structure of an organic layer and an inorganic layer, the organic layer may have an expansion of about 400 micrometers (μm) due to the process temperature, and the inorganic layer may have an expansion near 0 μm. However, since the stress of a thin film may be calculated by the product of a Young's modulus, i.e., a mechanical characteristic value of the thin film, and strain, the stress of the inorganic layer may be relatively greater than the stress of the organic layer. Therefore, delamination may occur or cracks may be formed in the inorganic layer due to the stress caused by the changes in the temperature.

According to an exemplary embodiment, since the stress formed by the first inorganic layer 35 may be removed by using the tensile stress of the first stress control layer 33 having a relatively high Young's modulus of about 110 GPa or more and disposed between the first inorganic layer 35 and the first organic layer 31, the total stress of the layers 35 and 33 may be controlled to be near 0. Therefore, the delamination or cracks of the layers 35 and 33 may be reduced or effectively prevented.

Interlayer adhesion may be an important factor for minimizing the delamination of the layers within the encapsulation layer 30. Critical adhesion may exist between layers in the encapsulation layer 30. The critical adhesion is a critical value of the interlayer adhesion. Where the interlayer adhesion is lower than the critical adhesion, interlayer delamination may occur. Therefore, the delamination between the inorganic layer and the organic layer may be reduced or effectively prevented by decreasing the critical adhesion between the layers as low as possible.

A critical adhesion between typical organic layer and inorganic layer may be in a range of about 0.7 newton per meter (N/m) to about 0.95 N/m. According to exemplary embodiment of the invention, a critical adhesion between the first organic layer 31 and the first stress control layer 33 may be decreased to about 0.3 N/m. Also, when the cross-sectional thickness of the first stress control layer 33 is about 2.5 nm or less, the critical adhesion between the first organic layer 31 and the first stress control layer 33 may be decreased to about 0.05 N/m or less. Therefore, since the critical adhesion between the first organic layer 31 and the first stress control layer 33 may be decreased, the delamination between the first organic layer 31 and the inorganic layers 35 and 33 or cracks may be reduced or effectively prevented.

The encapsulation layer 30 may further include a second inorganic layer and a second organic layer, and another exemplary embodiment of an organic light-emitting device including such an encapsulation layer, according to the invention, is illustrated in FIG. 2.

An encapsulation layer 50 of an organic light-emitting device 40 illustrated in FIG. 2 may include a first inorganic layer 35, a first organic layer 31, a second inorganic layer 45 and a second organic layer 41.

A first stress control layer 33 is disposed between the first inorganic layer 35 and the first organic layer 31. A second stress control layer 42 is disposed between the first organic layer 31 and the second inorganic layer 45. A third stress control layer 43 is disposed between the second inorganic layer 45 and the second organic layer 41. A stress control layer may be disposed between each pair of adjacent inorganic and organic layer, in a cross-sectional thickness direction, but the invention is not limited thereto.

Since the first stress control layer 33, the second stress control layer 42 and the third stress control layer 43 may play roles in controlling stress and reducing critical adhesion between layers of the encapsulation layer 50, the delamination between inorganic layers and organic layers within the encapsulation layer 50 may be reduced or effectively prevented. Thus, the durability of the encapsulation layer 50 in one or more exemplary embodiment of the invention including the above stress control layers may be improved. For detailed descriptions of the second stress control layer 42, the second inorganic layer 45, the third stress control layer 43 and the second organic layer 41, reference is made to the above descriptions of the first inorganic layer 35, the first stress control layer 33 and the first organic layer 31.

The encapsulation layer 50 may further include pluralities of additional inorganic layers and organic layers which are alternately disposed, and may further include stress control layers that are disposed between the inorganic layers and the organic layers. The number of the stacked inorganic, organic and stress control layers is not limited.

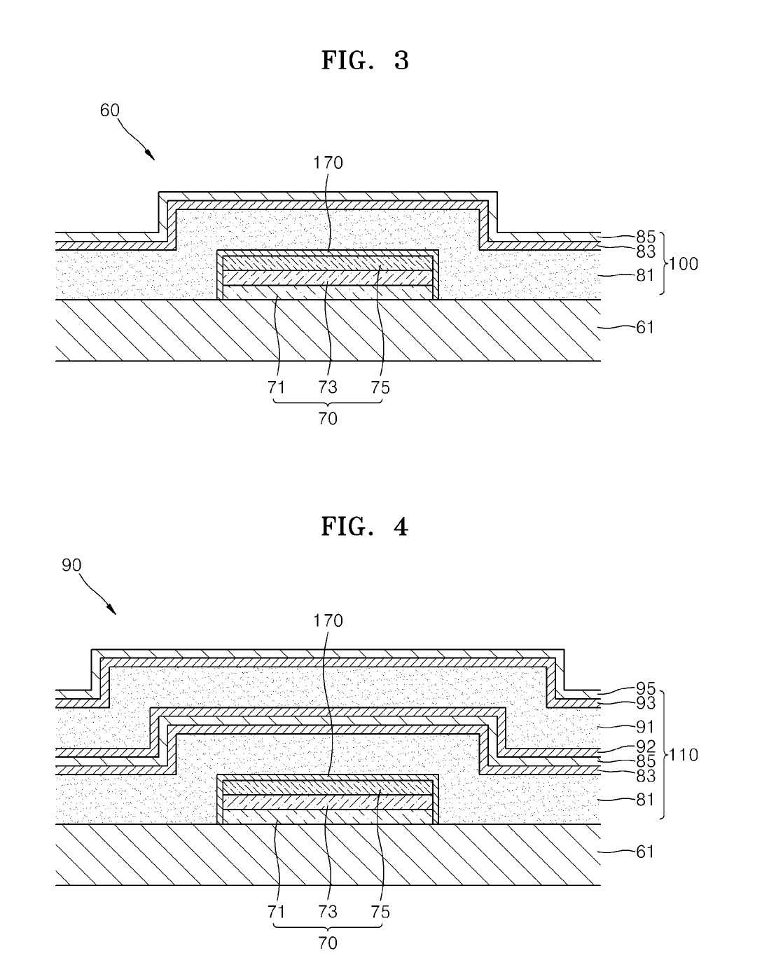

FIG. 3 is a cross-sectional view illustrating still another exemplary embodiment of an organic light-emitting device 60, according to the invention. An organic light-emitting diode 70 including a first electrode 71, an intermediate layer 73, and a second electrode 75 is disposed on a substrate 61 of the organic light-emitting device 60. For detailed description of the organic light-emitting diode 70, reference is made to the foregoing description of the organic light emitting diode 20.

A protective layer 170, which may reduce or effectively prevent the additional oxidation of the second electrode 75 of the organic light-emitting diode 70 due to oxygen and moisture, may be disposed on the organic light-emitting diode 70.

An encapsulation layer 100 may cover the organic light-emitting diode 70. The encapsulation layer 100 may include a first organic layer 81 and a first inorganic layer 85. A first stress control layer 83 having a higher Young's modulus than that of the first inorganic layer 85 may be between the first organic layer 81 and the first inorganic layer 85.

The first organic layer 81 may include one or more materials selected from an acryl-based resin, a methacryl-based resin, polyisoprene, a vinyl-based resin, an epoxy-based resin, a urethane-based resin, a cellulose-based resin and a perylene-based resin.

The inorganic layer 85 may include one or more materials selected from SiN_{X}, ZrOₓ, poly-Si, a-Si, Al, Cu, Cr, Au, Ag, Ta and alloys, Mg and alloys, steels, Ni-based alloys, Co-based alloys, Zr and alloys, polycarbonate and DLC. The Young's modulus of the first inorganic layer 85 may be in a range of about 40 GPa to about 90 GPa. The first inorganic layer 85 may be a nitride-based layer. A cross-sectional thickness of the first inorganic layer 85 may be in a range of about 30 nm to about 4,000 nm. In an exemplary embodiment of manufacturing the organic light-emitting device 60, the first inorganic layer 85 may be formed by magnetron sputtering (reactive), PECVD, E-beam evaporation, ARE, thermal evaporation and/or ion beam deposition (with sputter).

The first stress control layer 83 may be disposed between the first organic layer 81 and the first inorganic layer 85. The Young's modulus of the first stress control layer 83 may be greater than the Young's modulus of the first inorganic layer 85. The first stress control layer 83 may include AlOₓ, poly-diamond, TiC, SiC, WC, W, or Mo. The Young's modulus of the first stress control layer 83 may be in a range of about 110 GPa to about 1,000 GPa. The first stress control layer 83 may be an oxide-based layer. A cross-sectional thickness of the first stress control layer 83 may be in a range of about 0.5 nm to about 15 nm. In an exemplary embodiment of manufacturing the organic light-emitting device 60, the first stress control layer 83 may be formed by ALD, PLD, diode sputtering (non-magnetron sputtering), FTS and/or PECVD.

According to the illustrated exemplary embodiment, since the stress formed by the first inorganic layer 85 may be removed by using the tensile stress of the first stress control layer 83 having a relatively high Young's modulus of about 110 GPa or more and disposed between the first inorganic layer 85 and the first organic layer 81, the total stress of the layers 83 and 85 may be controlled to be near 0. Therefore, the delamination or cracks of the layers 83 and 85 may be reduced or effectively prevented.

A critical adhesion between typical organic layer and inorganic layer may be in a range of about 0.7 N/m to about 0.95 N/m. According to the exemplary embodiment of the invention, a critical adhesion between the first organic layer 81 and the first stress control layer 83 may be decreased to about 0.3 N/m. Also, when the cross-sectional thickness of the first stress control layer 83 is about 2.5 nm or less, the critical adhesion between the first organic layer 81 and the first stress control layer 83 may be decreased to about 0.05 N/m or less. Therefore, since the critical adhesion between the first organic layer 81 and the first stress control layer 83 may be decreased, the delamination between the first organic layer 81 and the layers 83 and 85 or cracks may be reduced or effectively prevented.

The encapsulation layer 100 may further include a second organic layer and a second inorganic layer, and another exemplary embodiment of an organic light-emitting device including such an encapsulation layer, according to the invention, is illustrated in FIG. 4.

An encapsulation layer 110 of an organic light-emitting device 90 illustrated in FIG. 4 may include a first organic layer 81, a first inorganic layer 85, a second organic layer 91 and a second inorganic layer 95.

A first stress control layer 83 is disposed between the first organic layer 81 and the first inorganic layer 85. A second stress control layer 92 is disposed between the first inorganic layer 85 and the second organic layer 91. A third stress control layer 93 is disposed between the second organic layer 91 and the second inorganic layer 95. A stress control layer may be disposed between each pair of adjacent organic and inorganic layer, in a cross-sectional thickness direction, but the invention is not limited thereto.

Since the first stress control layer 83, the second stress control layer 92 and the third stress control layer 93 may play roles in controlling stress and reducing critical adhesion between layers of the encapsulation layer 110, the delamination between inorganic layers and organic layers within the encapsulation layer 110 may be reduced or effectively prevented. Thus, the durability of the encapsulation layer 110 in one or more exemplary embodiment of the invention including the above stress control layers may be improved. For detailed descriptions of the second stress control layer 92, the second organic layer 91, the third stress control layer 93 and the second inorganic layer 95, reference is made to the above descriptions of the first organic layer 81, the first stress control layer 83 and the first inorganic layer 85.

The encapsulation layer 110 may further include pluralities of additional inorganic layers and organic layers which are alternately disposed, and may further include stress control layers that are disposed between the inorganic layers and the organic layers. The number of the stacked inorganic, organic, and stress control layers is not limited.

As described above, according to the one or more exemplary embodiment of the invention, the durability of an encapsulation layer of an organic light-emitting device may be improved.

It should be understood that the exemplary embodiments described therein should be considered in a descriptive sense only and not for purposes of limitation. Descriptions of features within each embodiment should typically be considered as available for other similar features in other exemplary embodiments.

While one or more exemplary embodiment of the invention has been described with reference to the figures, it will be understood by those of ordinary skill in the art that various changes in form and details may be made therein without departing from the spirit and scope of the invention as defined by the following claims.

What is claimed is:

1. An organic light-emitting device comprising:
a substrate;
an organic light-emitting diode on the substrate, and comprising: a first electrode, a second electrode, and an intermediate layer between the first electrode and the second electrode; and
an encapsulation layer covering the organic light-emitting diode, and comprising a first inorganic layer, a first stress control layer and a first organic layer which are sequentially stacked,
wherein a Young's modulus of the first stress control layer is greater than a Young's modulus of the first inorganic layer.

2. The organic light-emitting device of claim 1, wherein the Young's modulus of the first stress control layer is in a range of about 110 gigapascals to about 1,000 gigapascals.

3. The organic light-emitting device of claim 1, wherein the Young's modulus of the first inorganic layer is in a range of about 40 gigapascals to about 90 gigapascals.

4. The organic light-emitting device of claim 1, wherein the first stress control layer comprises AlOₓ, poly-diamond, TiC, SiC, WC, tungsten (W) or molybdenum (Mo).

5. The organic light-emitting device of claim 1, wherein a thickness of the first stress control layer is in a range of about 0.5 nanometer to about 15 nanometers.

6. The organic light-emitting device of claim 5, wherein the thickness of the first stress control layer is about 2.5 nanometers or less.

7. The organic light-emitting device of claim 1, wherein a critical adhesion between the first stress control layer and the first organic layer is in a range of about 0.01 newton per meter to about 0.3 newton per meter.

8. The organic light-emitting device of claim 1, wherein
the encapsulation layer further comprises a second stress control layer and a second inorganic layer sequentially stacked on the first organic layer, and
a Young's modulus of the second stress control layer is greater than a Young's modulus of the second inorganic layer.

9. The organic light-emitting device of claim 8, wherein
the encapsulation layer further comprises a third stress control layer and a second organic layer sequentially stacked on the second inorganic layer, and
a Young's modulus of the third stress control layer is greater than the Young's modulus of the second inorganic layer.

10. The organic light-emitting device of claim 1, further comprising a protective layer between the organic light-emitting diode and the encapsulation layer.

11. An organic light-emitting device comprising:
a substrate;
an organic light-emitting diode on the substrate, and comprising a first electrode, a second electrode, and an intermediate layer between the first electrode and the second electrode; and
an encapsulation layer covering the organic light-emitting diode, and comprising a first organic layer, a first stress control layer and a first inorganic layer which are sequentially stacked,
wherein a Young's modulus of the first stress control layer is greater than a Young's modulus of the first inorganic layer.

12. The organic light-emitting device of claim 11, wherein the Young's modulus of the first stress control layer is in a range of about 110 gigapascals to about 1,000 gigapascals.

13. The organic light-emitting device of claim 11, wherein the Young's modulus of the first inorganic layer is in a range of about 40 gigapascals to about 90 gigapascals.

14. The organic light-emitting device of claim 11, wherein the first stress control layer comprises AlOₓ, poly-diamond, TiC, SiC, WC, tungsten (W) or molybdenum (Mo).

15. The organic light-emitting device of claim 11, wherein a thickness of the first stress control layer is in a range of about 0.5 nanometer to about 15 nanometers.

16. The organic light-emitting device of claim 15, wherein the thickness of the first stress control layer is about 2.5 nanometers or less.

17. The organic light-emitting device of claim 11, wherein a critical adhesion between the first stress control layer and the first organic layer is in a range of about 0.01 newton per meter to about 0.3 newton per meter.

18. The organic light-emitting device of claim 11, wherein
the encapsulation layer further comprises a second stress control layer and a second organic layer sequentially stacked on the first inorganic layer, and
a Young's modulus of the second stress control layer is greater than the Young's modulus of the first inorganic layer.

19. The organic light-emitting device of claim 18, wherein
the encapsulation layer further comprises a third stress control layer and a second inorganic layer sequentially stacked on the second organic layer, and
a Young's modulus of the third stress control layer is greater than a Young's modulus of the second inorganic layer.

20. The organic light-emitting device of claim 11, further comprising a protective layer between the organic light-emitting diode and the encapsulation layer.
